(19) United States
(12) Patent Application Publication
(10) Pub. No.: US 2025/0385670 A1
(43) Pub. Date: Dec. 18, 2025

(54) GATE DRIVER CIRCUIT AND MOTOR DRIVING DEVICE

(71) Applicant: ROHM CO., LTD., Kyoto-shi (JP)

(72) Inventor: Hisashi SUGIE, Kyoto-shi (JP)

(21) Appl. No.: 19/227,644

(22) Filed: Jun. 4, 2025

(30) Foreign Application Priority Data
Jun. 12, 2024 (JP) 2024-095237

(51) Int. Cl. H03K 17/687; H02P 23/00

(52) U.S. Cl. CPC H03K 17/687; H02P 23/00; H03K 2217/0063; H03K 2217/0072

(57) ABSTRACT

An under voltage detection circuit compares a potential difference between a bootstrap line and an output line with a threshold voltage. A first resistor comprises a first end connected to the bootstrap line. A Zener diode comprises a cathode connected to the bootstrap line and has a parasitic capacitance between the cathode and a substrate. A first transistor comprises a source connected to the output line, and a drain and a gate connected to a second end of the first resistor. A comparator compares a voltage drop across a second resistor with a threshold voltage and generates an under voltage detection signal.

### CROSS REFERENCE TO RELATED APPLICATIONS

The present invention claims priority under 35 U.S.C. § 119 to Japanese Application No. 2024-095237, filed on Jun. 12, 2024, the entire contents of which being incorporated herein by reference.

### TECHNICAL FIELD

The present disclosure relates to a gate driver circuit.

### BACKGROUND

Motor driving circuits and power supply circuits include switching circuits such as single-phase inverters, three-phase inverters, H-bridge circuits, etc., as well as gate driver circuits that drive the switching circuits.

When a high-side transistor is formed of an N-type transistor, i.e., an N-channel MOSFET (Metal Oxide Semiconductor Field Effect Transistor), an NPN-type bipolar transistor, an IGBT (Insulated Gate Bipolar Transistor), etc., a bootstrap circuit is used.

In order to reliably turn on the high-side transistor, it is necessary that a potential difference between an output line connected to a source of the high-side transistor and the bootstrap line be higher than a threshold voltage V_{GS(th)} of the high-side transistor.

### PRIOR ART DOCUMENT

### Patent Publication

[Patent document 1] Japan Patent Publication No. 2020-087942.

### BRIEF DESCRIPTION OF THE DRAWINGS

FIG. 1 is a circuit diagram of a switching circuit comprising a gate driver circuit according to an embodiment.

FIG. 2 is a circuit diagram of an under voltage detection circuit according to an embodiment.

FIG. 3 is a diagram illustrating an operation of an under voltage detection circuit.

FIG. 4 is a circuit diagram of an under voltage detection circuit according to an example.

FIG. 5 is a circuit diagram of a motor driving device according to an embodiment.

### DETAILED DESCRIPTION OF THE EMBODIMENTS

An overview of some exemplary embodiments of the present disclosure are described. This overview serves as a preface to the detailed description that follows, is intended to provide a basic understanding of one or more embodiments by simplifying some concepts related to the embodiments, and is not intended to limit the scope of the invention or disclosure. Additionally, this overview is not an exhaustive summary of all possible embodiments, nor is it intended to limit essential elements of the embodiments. For convenience, “one embodiment” may be used to refer to one embodiment (example or variation) or multiple embodiments (examples or variations) disclosed in this specification.

A gate driver circuit according to one embodiment drives an N-type high-side transistor. The gate driver circuit comprises an output line (also referred to as a switching line) to be connected to a source of the high-side transistor, a bootstrap line to be connected to the high-side transistor via a bootstrap capacitor, a voltage source that applies a constant voltage to the bootstrap line, and an under voltage (UV: Under Voltage) detection circuit that compares a potential difference between the bootstrap line and the output line with a threshold voltage. The under voltage detection circuit includes a first resistor comprising a first end connected to the bootstrap line, a Zener diode comprising a cathode connected to the bootstrap line and having a parasitic capacitance between the cathode and a substrate, an N-type first transistor comprising a source connected to the output line and a drain and a gate connected to a second end of the first resistor, an N-type second transistor comprising a source connected to the output line and a gate connected to a gate of the first transistor, an N-type third transistor comprising a source connected to a drain of the second transistor and a drain and a gate connected to an anode of the Zener diode, an N-type fourth transistor comprising a source connected to the source of the third transistor and a gate connected to the gate of the third transistor, a second resistor connected between the bootstrap line and a drain of the fourth transistor, and a comparator that compares a voltage drop across the second resistor with the threshold voltage.

According to this configuration, the parasitic capacitance of the Zener diode exists between the bootstrap line and the substrate, and therefore voltage level fluctuations of the bootstrap line and the output line caused by switching do not affect an operating point of the under voltage detection circuit. Therefore, accurate under voltage detection is possible even during switching operations. Additionally, a current consumption of the under voltage detection circuit can be greatly reduced.

In one embodiment, the first resistor and the second resistor may be of a same type. In one embodiment, the first resistor and the second resistor may be disposed adjacent to each other. As a result, a relative accuracy of resistance values of the first resistor and the second resistor can be enhanced, and therefore variations in threshold values of under voltage detection can be suppressed.

In one embodiment, the comparator may include a P-type fifth transistor comprising a source connected to the bootstrap line and a gate connected to the drain of the fourth transistor, and a third resistor connected between a drain of the fifth transistor and ground.

In one embodiment, the first transistor to the fourth transistor may be floating MOS transistors.

In one embodiment, the first resistor and the second resistor may be formed on a well connected to the bootstrap line.

A motor driving device according to one embodiment may include any one of the gate driver circuits described above.

### Embodiments

Hereinafter, preferable embodiments are described with reference to the figures. Identical or equivalent elements, components, processes shown in each figures are denoted by same reference numerals, and redundant descriptions are omitted as appropriate. Furthermore, the embodiments are examples rather than limitations to the invention, and all features or combinations thereof described in the embodiments are not necessarily essential to the invention.

In this specification, “a state in which component A is connected to component B” includes not only cases in which component A and component B are physically directly connected to each other, but also cases in which component A and component B are indirectly connected to each other via other components that do not substantially affect their electrical connection state or do not impair functions or effects achieved by their combination.

Similarly, “a state in which component C is disposed between component A and component B” includes not only cases in which component A and component C, or component B and component C are directly connected, but also cases where they are indirectly connected via other components that do not substantially affect their electrical connection state or do not impair functions or effects achieved by their combination.

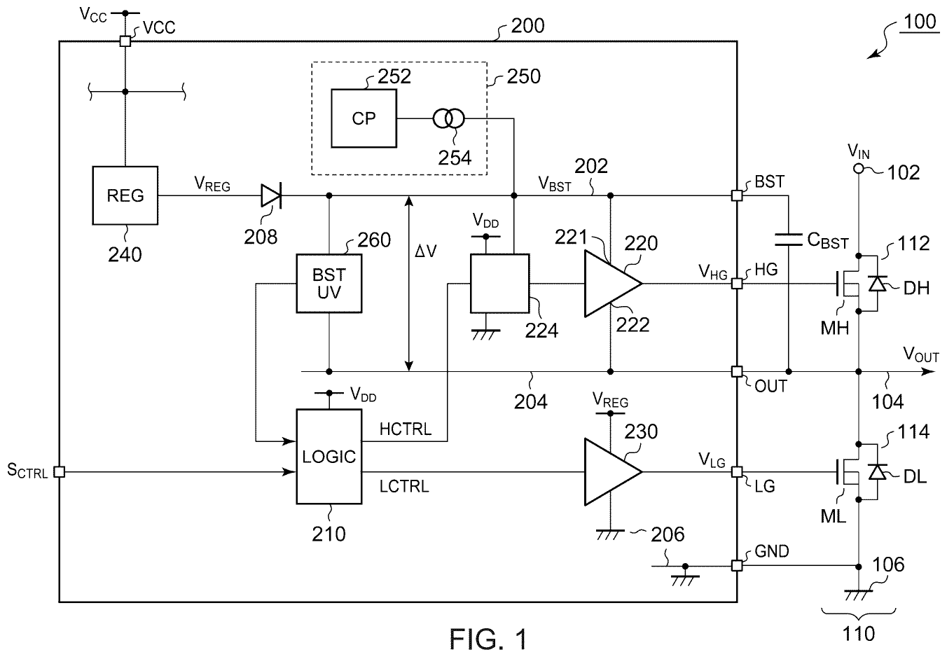

FIG. 1 is a circuit diagram of a switching circuit 100 that comprises a gate driver circuit 200 according to an embodiment. The switching circuit 100 comprises a bridge circuit 110 and a gate driver circuit 200. Herein, only a configuration of one phase of the switching circuit 100 is shown, but the switching circuit 100 may be single-phase, may be three-phase, or may be an H-bridge circuit.

The bridge circuit 110 comprises an upper arm 112 provided between a power supply line (input line) 102 and an output terminal (output line) 104, and a lower arm 114 provided between the output line 104 and a ground line 106. The upper arm 112 includes a high-side transistor MH and a flywheel diode (flyback diode) DH connected in parallel. The lower arm 114 includes a low-side transistor ML and a flywheel diode DL connected in parallel. In this embodiment, the high-side transistor MH and the low-side transistor ML are N-channel MOSFETs, and their body diodes each serves as the flywheel diodes DH, DL. Depending on the application, a shunt resistor for current detection may be inserted between the low-side transistor ML and the ground line 106.

The gate driver circuit 200 controls the high-side transistor MH and the low-side transistor ML of the bridge circuit 110 based on the control signal S_{CTRL}. The control signal S_{CTRL} may have three states ϕ1 to ϕ3.

The first state ϕ1 is a state which indicates a high output state (V_{OUT}=V_{IN}) where the high-side transistor MH is on and the low-side transistor ML is off.

The second state ϕ2 is a state which indicates a low output state (V_{OUT}=0V) where the high-side transistor MH is off and the low-side transistor ML is on.

The third state ϕ3 is a state which indicates a high-impedance state (V_{OUT}=HiZ) where the high-side transistor MH is off and the low-side transistor ML is off.

The gate driver circuit 200 comprises a control circuit 210, a high-side driver 220, a level shifter 224, a low-side driver 230, a regulator 240, a charging circuit 250, a under voltage detection circuit 260, and is a functional IC integrated onto one semiconductor substrate. The gate driver circuit 200 may be a gate driver IC (Integrated Circuit) or may be a portion of a motor driver IC or a controller IC of a DC/DC converter.

A high-side gate pin HG of the gate driver circuit 200 is connected to a gate of the high-side transistor MH, and a low-side gate pin LG is connected to a gate of the low-side transistor ML. A ground pin GND is connected to a source of the low-side transistor ML. A switching pin (output pin) OUT is connected to the output line 104. A bootstrap capacitor CBST is externally connected between a bootstrap pin BST and the switching pin OUT.

A bootstrap line 202 is connected to the bootstrap pin BST, a switching line 204 is connected to the switching pin OUT, and a ground line 206 is connected to the ground pin GND. The regulator 240 generates a constant voltage V_{REG}. The constant voltage V_{REG} is set to be higher than threshold voltages V_{GS(th)} of the high-side transistor MH and the low-side transistor ML. For example, the constant voltage V_{REG} is approximately 12V.

The constant voltage V_{REG} is applied to the bootstrap line 202 via a rectifying element 208. The rectifying element 208 and the bootstrap capacitor CBST form a bootstrap circuit, and by utilizing a switching operation of the bridge circuit 110, a bootstrap voltage V_{BST}, which is higher than a voltage (switching voltage) V_{OUT} of the switching line 204 by a predetermined voltage ΔV, is generated at the bootstrap line 202. When a forward voltage of the rectifying element 208 is Vf, ΔV=V_{REG}−Vf.

The control circuit 210 generates a high-side control signal HCTRL and a low-side control signal LCTRL such that when the control signal S_{CTRL} is in the first state ϕ1, the high-side transistor MH is on and the low-side transistor ML is off, when the control signal S_{CTRL} is in the second state ϕ2, the high-side transistor MH is off and the low-side transistor ML is on, and when the control signal S_{CTRL} is in the third state ϕ3, the high-side transistor MH is off and the low-side transistor ML is off.

The high-side control signal HCTRL generated by the control circuit 210 is level-shifted up by a level shifter 224 and supplied to a high-side driver 220. The high-side driver 220 controls a gate voltage V_{HG} of the high-side transistor MH in response to the high-side control signal HCTRL which is level-shifted. An upper power supply node 221 of the high-side driver 220 is connected to the bootstrap line 202 and is supplied with the bootstrap voltage V_{BST}. A lower power supply node 222 is connected to the switching line 204 and is supplied with the switching voltage V_{OUT}. The high-side driver 220 outputs either the gate high voltage V_{BST} or the gate low voltage V_{OUT} to the high-side gate pin HG in response to the high-side control signal HCTRL.

The high-side driver 220 may be configured so that a driving capability is controllable. The high-side driver 220 is configured as either a current-driven type or a voltage-driven type. In the case of a current-driven high-side driver, its driving capability can be understood as an amount of current sourced to the gate of the high-side transistor MH or an amount of current sunk from the gate. In the case of a voltage-driven high-side driver, its driving capability can be understood as an output impedance. In short, the high-side driver 220 may be configured to be able to switch a slope (slew rate) of the gate voltage V_{HG} generated at the high-side gate pin HG.

A low-side driver 230 controls a gate voltage V_{LG} of the low-side transistor ML in response to the low-side control signal LCTRL. A power supply voltage V_{DD} is supplied to an upper power supply node 231 of the low-side driver 230, and a ground voltage is supplied to a lower power supply node 232 of the low-side driver 230.

Similar to the high-side driver 220, the low-side driver 230 may be configured so that a driving capability is controllable, and may be configured to be able to switch a slope of the gate voltage V_{LG} generated at the low-side gate pin LG.

This switching circuit 100 supports an operation mode where the high-side transistor MH is fixed to be on at a 100% duty cycle. When the high-side transistor MH is fixed to be on, the bootstrap capacitor CBST becomes unable to be charged by the bootstrap circuit. In this operation mode, the charging circuit 250 becomes active and charges the bootstrap line 202 to a voltage level higher than the input voltage V_{IN}. The configuration of the charging circuit 250 is not limited, but it may include, for example, a charge pump circuit 252 and a constant current source 254.

There may be cases where the power supply voltage V_{CC} supplied to the gate driver circuit 200 decreases. When the power supply voltage V_{CC} drops to a region lower than a target level (e.g., 12V) of the constant voltage V_{REG}, the constant voltage V_{REG} becomes lower than the target level. Then, if the constant voltage V_{REG} becomes lower than the threshold voltage V_{GS(th)} of the high-side transistor MH, the high-side transistor MH becomes unable to be turned on. An under voltage detection circuit 260 monitors a potential difference ΔV between the bootstrap line 202 and the switching line 204 and detects an under voltage state where the potential difference ΔV is lower than a predetermined threshold voltage V_{UV}.

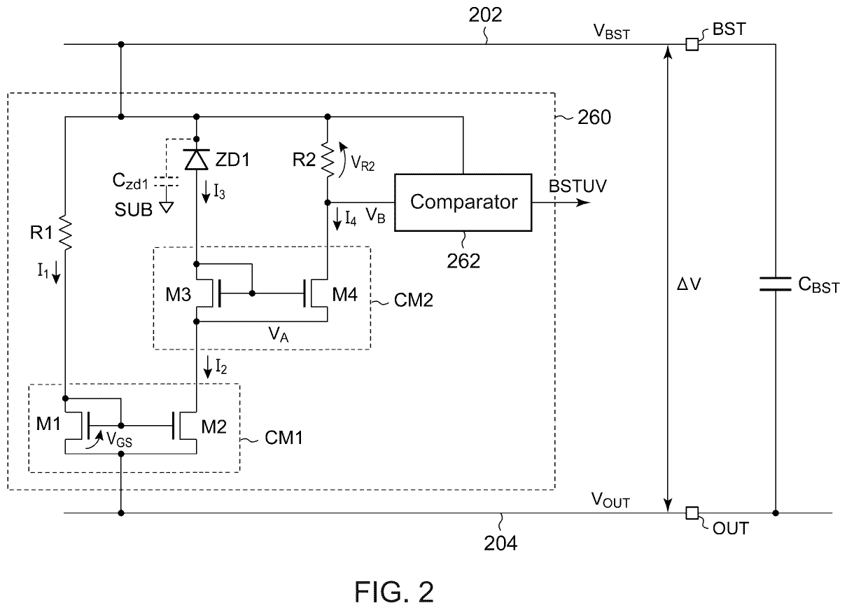

FIG. 2 is a circuit diagram of the under voltage detection circuit 260 according to an embodiment. The under voltage detection circuit 260 includes a first resistor R1, a second resistor R2, a first transistor M1, a second transistor M2, a third transistor M3, a fourth transistor M4, which are NMOS transistors, a Zener diode ZD1, and a comparator 262.

A first end of the first resistor R1 is connected to the bootstrap line 202. A cathode of the Zener diode ZD1 is connected to the bootstrap line 202. The Zener diode ZD1 has a parasitic capacitance Czd1 between the cathode and a semiconductor substrate (SUB).

The Zener diode ZD1 is described. The cathode of the Zener diode ZD1 is adjacent to the SUB (substrate), and the parasitic capacitance between the cathode and the substrate is large. Additionally, a voltage between an anode and the cathode is approximately 5.2V.

A source of the first transistor M1 is connected to the switching line 204, and a drain and a gate of the first transistor M1 are connected to a second end of the first resistor R1. A source of the second transistor M2 is connected to the switching line 204, and a gate of the second transistor M2 is connected to the gate of the first transistor M1. The first transistor M1 and the second transistor M2 form a current mirror circuit CM1.

A source of the third transistor M3 is connected to a drain of the second transistor M2, and a drain and a gate of the third transistor M3 are connected to an anode of the Zener diode ZD1. A source of the fourth transistor M4 is connected to the source of the third transistor M3, and a gate of the fourth transistor M4 is connected to the gate of the third transistor M3. The third transistor M3 and the fourth transistor M4 form a current mirror circuit CM2.

The second resistor R2 is connected between the bootstrap line 202 and a drain of the fourth transistor M4. The comparator 262 compares a voltage drop V_{R2} across the second resistor R2 with the threshold voltage Vth, negates an under voltage detection signal BSTUV when V_{R2}>Vth, and asserts the under voltage detection signal BSTUV when V_{R2}<Vth.

It is desirable that the first resistor R1 and the second resistor R2 are resistors of a same type (same structure). Furthermore, it is desirable that the first resistor R1 and the second resistor R2 are disposed adjacent to each other within a common well. As a result, a relative variation in resistance values of the first resistor R1 and the second resistor R2 can be suppressed.

Furthermore, it is desirable that the first transistor M1 to the fourth transistor M4 are all formed of floating NMOS transistors. By connecting a floating well, which has a low impedance, to a power supply line based on the switching line 204, an influence of switching on a signal system, which has a high impedance, specifically an input signal (V_{B}) or an output signal (BSTUV) of the comparator 262, can be prevented.

The above is the configuration of the under voltage detection circuit 260. Next, an operation of the under voltage detection circuit 260 is described.

When a gate-source voltage of the first transistor M1 is Vas, a relationship of equation (1) holds between a current I₁ flowing through the first resistor R1 and ΔV=V_{BST}−V_{OUT}.

I₁=(ΔV−V_{GS})/R1 (1)

A Zener voltage of the Zener diode ZD1 is V_{ZD}, and a gate-source voltage of the third transistor M3 is V_{GS}. When ΔV>V_{ZD}+V_{GS}, the Zener diode ZD1 is conductive. V_{ZD}+V_{GS} is a voltage equivalent to a threshold voltage V_{UV} of the under voltage detection circuit 260.

When ΔV>V_{UL}, a current I₂ proportional to the current I₁ flows through the second transistor M2. Since the third transistor M3 and the fourth transistor M4 form a current mirror circuit CM2, currents I₃ and I₄ flow through the third transistor M3 and the fourth transistor M4 in a ratio according to their size parameters (W/L). W is a gate width, and L is a gate length. For example, when the size parameters W/L of the third transistor M3 and the fourth transistor M4 are equal, I₃=I₄=I₂/2.

When the current I₄ flows, a voltage drop V_{R2}=I₄×R2 occurs across the second resistor R2. The threshold voltage Vth of the comparator 262 is set to be lower than the voltage drop V_{R2} when the Zener diode ZD1 is conductive, i.e., when ΔV>V_{UL} holds, and thus the under voltage detection signal BSTUV is negated.

When ΔV<V_{ZD}+V_{GS}, the Zener diode ZD1 is cut off. At this time, the current I₂ no longer flows through the second transistor M2, and the current also stops flowing through the third transistor M3 and the fourth transistor M4. As a result, the voltage drop V_{R2} across the second resistor R2 becomes zero, and

V_{R2}<Vth.

Therefore, the under voltage detection signal BSTUV is asserted.

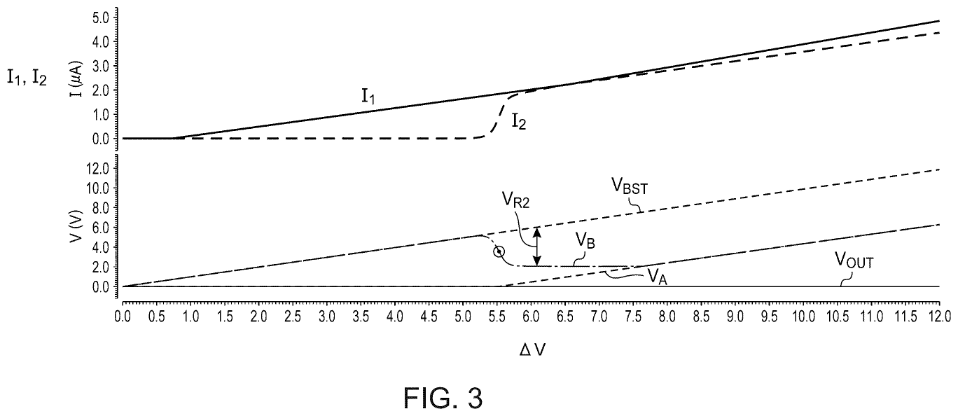

FIG. 3 is a diagram illustrating an operation of the under voltage detection circuit 260. A horizontal axis represents the potential difference ΔV between the bootstrap line 202 and the switching line 204. Herein, V_{OUT}=0V, that is, a switching of the bridge circuit 110 is stopped. FIG. 3 shows the currents I₁, I₂, the bootstrap voltage V_{BST}, the output voltage V_{OUT}, a drain voltage V_{A} of the second transistor M2, and a drain voltage V_{B} of the fourth transistor M4. A potential difference between the voltages V_{BST} and V_{B} is the voltage drop V_{R2} across the second resistor R2.

In this example, the threshold voltage V_{UV} is around 5.5V, and when ΔV<V_{UV}, the current stops flowing through the Zener diode ZD1, and the voltage drop V_{R2} across the second resistor R2 becomes lower than the threshold voltage Vth of comparator 262.

As such, according to the under voltage detection circuit 260, an under voltage state of the potential difference ΔV can be detected.

In the under voltage detection circuit 260, the cathode of the Zener diode ZD1 is connected to the bootstrap line 202, and an influence of its parasitic capacitance Czd1 on electrical signals generated in the under voltage detection circuit 260, specifically an influence on the voltages V_{A}, V_{B}, V_{R2}, and the currents I₁, I₂, I₃, I₄ flowing through the under voltage detection circuit 260, is very small. Therefore, even during the switching operation of the bridge circuit 110, accurate under voltage detection is possible.

Additionally, the under voltage detection circuit 260 has advantages of low current consumption. In the circuit disclosed in Patent Document 1 (Japan Patent Publication No. 2020-087942), a current consumption exceeding 50 μA is required, but in the under voltage detection circuit 260 of FIG. 2, the current consumption can be reduced to 10 μA or less.

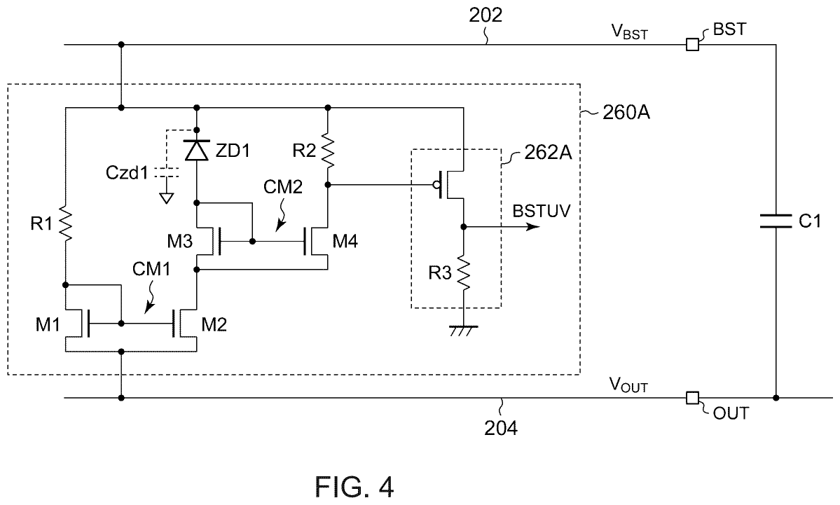

FIG. 4 is a circuit diagram of an under voltage detection circuit 260A according to an embodiment. In this embodiment, the comparator 262A includes a third resistor R3 and a fifth transistor M5, which is a PMOS transistor. A source of the fifth transistor M5 is connected to the bootstrap line 202, and a gate of the fifth transistor M5 is connected to the drain of the fourth transistor M4. The third resistor R3 is connected between a drain of the fifth transistor M5 and ground. A threshold voltage Vth of this comparator 262A is a threshold voltage V_{GS(th)} of the fifth transistor M5. That is, when the voltage drop V_{R2} across the resistor R2 is greater than the threshold voltage V_{GS(th)}, the fifth transistor M5 is turned on, and the under voltage detection signal BSTUV becomes high (negated). Conversely, when the voltage drop V_{R2} across the resistor R2 becomes smaller than the threshold voltage V_{GS(th)}, the fifth transistor M5 is turned off, and the under voltage detection signal BSTUV becomes low.

Next, an application of the switching circuit 100 is described. The switching circuit 100 can be suitably used in motor driving circuits.

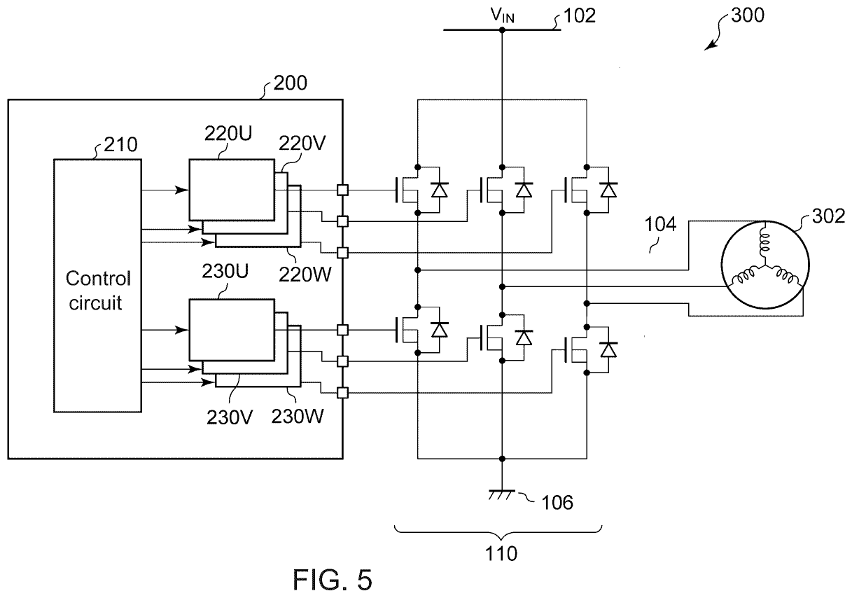

FIG. 5 is a circuit diagram of a motor driving device 300 according to an embodiment. The motor driving device 300 drives a three-phase motor 302, which is a load, and controls a rotational state.

The motor driving device 300 comprises a bridge circuit 110 and a gate driver circuit 200, and is configured such that the above-mentioned switching circuit 100 has three phases. The bridge circuit 110 is a three-phase inverter and comprises U phase, V phase, and W phase legs, and each phase leg comprises an upper arm and a lower arm.

The gate driver circuit 200 comprises a control circuit 210, high-side drivers 220U to 220W, and low-side drivers 230U to 230W. The control circuit 210 generates a control signal indicating a state of six arms that form the bridge circuit 110 based on a state of the three-phase motor 302, which is the load.

Although a three-phase motor is used as an example herein, a single-phase motor may be used. In this case, the bridge circuit 110 becomes an H-bridge circuit.

Next, applications of the motor driving device 300 are described. The motor driving device 300 can be used to control a spindle motor of a hard disk or control a lens drive motor of an imaging device. Alternatively, it can be used to drive a head motor or paper feed motor of a printer. Alternatively, the motor driving device 300 can be used to drive motors in an electric vehicle, a hybrid vehicle, etc.

The embodiments are merely exemplary, and those skilled in the art can recognize that various modification examples are possible in a combination of each of these components or processing processes, and that such modification examples are within the scope of the present disclosure or the present invention. Such modification examples are described below.

### Modification Example 1

The configuration of the comparator 262 is not limited to the configuration in FIG. 4, and a voltage comparator using a differential amplifier may be used.

### Modification Example 2

The application of the switching circuit 100 is not limited to the motor driving device 300. For example, the switching circuit 100 can be suitably used in switching regulators (DC/DC converters), various power conversion devices (inverters, converters, etc.), inverters for lighting discharge lamps, digital audio amplifiers, etc. Therefore, the switching circuit 100 can be used in consumer devices including electronic equipment and home appliances, automobiles and in-vehicle components, industrial vehicles and industrial machinery.

Although the embodiments related to the present disclosure have been described using specific terms, this description is merely an example to facilitate understanding and is not intended to limit the scope of the present disclosure or claims. The scope of the present invention is defined by the claims, and thus embodiments, examples, and modification examples not described herein are also included within the scope of the present invention.

### APPENDIX

This specification discloses the following techniques.

### Item 1

A gate driver circuit, driving an N-type high-side transistor, comprising:
an output line to be connected to a source of the high-side transistor;
a bootstrap line to be connected to the high-side transistor via a bootstrap capacitor;
a voltage source applying a constant voltage to the bootstrap line; and
an under voltage detection circuit comparing a potential difference between the bootstrap line and the output line with a threshold voltage,
wherein the under voltage detection circuit includes:
a first resistor comprising a first end connected to the bootstrap line;
a Zener diode comprising a cathode connected to the bootstrap line and having a parasitic capacitance between the cathode and a substrate;
an N-type first transistor comprising a source connected to the output line, and a drain and a gate connected to a second end of the first resistor;
an N-type second transistor comprising a source connected to the output line, and a gate connected to the gate of the first transistor;
an N-type third transistor comprising a source connected to a drain of the second transistor, and a drain and a gate connected to an anode of the Zener diode;
an N-type fourth transistor comprising a source connected to the source of the third transistor, and a gate connected to the gate of the third transistor;
a second resistor connected between the bootstrap line and a drain of the fourth transistor; and
a comparator comparing a voltage drop across the second resistor with a threshold voltage.

### Item 2

The gate driver circuit of Item 1, wherein the first resistor and the second resistor are of a same type.

### Item 3

The gate driver circuit of Item 1 or 2, wherein the first resistor and the second resistor are disposed adjacent to each other.

### Item 4

The gate driver circuit of any one of Items 1 to 3, wherein the comparator includes:
a P-type fifth transistor comprising a source connected to the bootstrap line and a gate connected to the drain of the fourth transistor; and
a third resistor connected between a drain of the fifth transistor and ground.

### Item 5

The gate driver circuit of any one of Items 1 to 4, wherein the first transistor to the fourth transistor are floating MOS transistors.

### Item 6

The gate driver circuit of any one of Items 1 to 5, wherein the first resistor and the second resistor are formed on a well connected to the bootstrap line.

### Item 7

A motor driving device, comprising the gate driver circuit of any one of Items 1 to 6.

1. A gate driver circuit, driving an N-type high-side transistor, comprising:
an output line to be connected to a source of the high-side transistor;
a bootstrap line to be connected to the high-side transistor via a bootstrap capacitor;
a voltage source applying a constant voltage to the bootstrap line; and
an under voltage detection circuit comparing a potential difference between the bootstrap line and the output line with a threshold voltage,
wherein the under voltage detection circuit includes:
a first resistor comprising a first end connected to the bootstrap line;
a Zener diode comprising a cathode connected to the bootstrap line and having a parasitic capacitance between the cathode and a substrate;
an N-type first transistor comprising a source connected to the output line, and a drain and a gate connected to a second end of the first resistor;
an N-type second transistor comprising a source connected to the output line, and a gate connected to the gate of the first transistor;
an N-type third transistor comprising a source connected to a drain of the second transistor, and a drain and a gate connected to an anode of the Zener diode;
an N-type fourth transistor comprising a source connected to the source of the third transistor, and a gate connected to the gate of the third transistor;
a second resistor connected between the bootstrap line and a drain of the fourth transistor; and
a comparator comparing a voltage drop across the second resistor with a threshold voltage.

2. The gate driver circuit of claim 1, wherein the first resistor and the second resistor are of a same type.

3. The gate driver circuit of claim 1, wherein the first resistor and the second resistor are disposed adjacent to each other.

4. The gate driver circuit of claim 1, wherein the comparator includes:
a P-type fifth transistor comprising a source connected to the bootstrap line and a gate connected to the drain of the fourth transistor; and
a third resistor connected between a drain of the fifth transistor and ground.

5. The gate driver circuit of claim 1, wherein the first transistor to the fourth transistor are floating MOS transistors.

6. The gate driver circuit of claim 1, wherein the first resistor and the second resistor are formed on a well connected to the bootstrap line.

7. A motor driving device, comprising the gate driver circuit of claim 1.
